(19) United States
(12) Patent Application Publication
(10) Pub. No.: US 2009/0149029 A1
(43) Pub. Date: Jun. 11, 2009

(54) PRODUCTION METHOD FOR SEMICONDUCTOR DEVICE

(75) Inventor: Ryuta Maruyama, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto-shi (JP)

(21) Appl. No.: 12/084,775

(22) PCT Filed: Nov. 10, 2006
(86) PCT No.: PCT/JP2006/322442

§ 371 Date: May 9, 2008

(30) Foreign Application Priority Data
Nov. 11, 2005 (JP) 2005-327696

(51) Int. Cl. H01L 21/302

(52) U.S. Cl. 438/742; 257/E21.214; 438/720

(57) ABSTRACT

An inventive semiconductor device production method is a method for producing a semiconductor device having a metal interconnection by etching a metal film including a lower layer of a first metal material and an upper layer of a second metal material different from the first metal material. In the production method, the upper layer is selectively etched under conditions such that an etching rate for the upper layer is higher than an etching rate for the lower layer. The etching is terminated when the lower layer is exposed. Thereafter, the upper layer is over-etched under conditions such that the etching rate for the upper layer is substantially equal to the etching rate for the lower layer. Then, the lower layer is selectively etched.

### TECHNICAL FIELD

The present invention relates to a production method for a semiconductor device such as an LSI.

### BACKGROUND ART

In some semiconductor devices such as LSIs, a metal interconnection formed on a semiconductor substrate by patterning have a laminate structure including a Ti (titanium) layer and a TiN (titanium nitride) layer for improvement of the reliability thereof.

In a process for forming the metal interconnection by the patterning, as shown in FIG. 4(a), an AlCu layer 92 of an alloy of Al (aluminum) and Cu (copper), a Ti/TiN layer 93 including the Ti sublayer and the TiN sublayer and a BARC (Bottom Anti-Reflective Coating) layer 94, for example, are formed in this order in stacked relation on a semiconductor substrate 91. Thereafter, a resist pattern 95 is formed in a metal interconnection formation region on the BARC layer 94 by a photolithography technique. Then, unnecessary portions of the Ti/TiN layer 93 and the BARC layer 94 are removed by performing dry-etching (plasma-etching) with the resist pattern 95 used as a mask under conditions (defined by the types of gases, an output and the like) such that an etching rate for the Ti/TiN layer 93 and the BARC layer 94 is higher than an etching rate for the AlCu layer 92.

An upper layer etching process for the removal of the unnecessary portions of the Ti/TiN layer 93 and the BARC layer 94 is terminated after a lapse of a predetermined period from detection of an etching termination point (at which the AlCu layer 92 is exposed) for assuredly removing the unnecessary portion of the Ti/TiN layer 93. That is, the upper layer etching process includes a main etching step to be performed until the etching termination point is detected, and an over-etching step during which the etching is further continued after the main etching step.

After the termination of the upper layer etching process, dry-etching is performed to remove an unnecessary portion of the AlCu layer 92 with the resist pattern 95 used as a mask as shown in FIG. 4(c). After the removal of the unnecessary portion of the AlCu layer 92, the dry etching for the removal of the unnecessary portion of the AlCu layer 92 is terminated, and the resist pattern 95 on the BARC layer 94 is removed. Thus, a pattern of a metal interconnection 96 is provided on the semiconductor substrate 91 as shown in FIG. 4(d).

Patent Document 1: Japanese Unexamined Patent Publication No. 11 (1999)-97428

### DISCLOSURE OF THE INVENTION

### Problems to be Solved by the Invention

However, if the over-etching step is performed under the same conditions as the main etching step, i.e., if the dry etching is performed under the conditions such that the etching rate for the Ti/TiN layer 93 and the BARC layer 94 is higher than the etching rate for the AlCu layer 92, etching species such as radicals non-reactive with the AlCu layer 92 attack side faces of the Ti/TiN layer 93 as shown in FIG. 4(b) to result in etching of the side faces of the Ti/TiN layer 93 (side etching), because almost all the unnecessary portions of the Ti/TiN layer 93 and the BARC layer 94 have been removed. If the side etching occurs, a portion of the metal interconnection 96 formed from the Ti/TiN layer 93 and the BARC layer 94 is lost, resulting in variations in resistance of the metal interconnection 96.

It is therefore an object of the present invention to provide a semiconductor device production method which can suppress the side etching of an upper layer of a metal interconnection.

### Means for Solving the Problems

An inventive semiconductor device production method to attain the aforementioned object is a method for producing a semiconductor device having a metal interconnection by etching a metal layer {film} including a lower layer of a first metal material and an upper layer of a second metal material different from the first metal material, the method including the steps of: performing an upper layer main etching process to selectively etch the upper layer under conditions such that an etching rate for the upper layer is higher than an etching rate for the lower layer, the upper layer main etching process being terminated when the lower layer is exposed by the etching process; performing an upper layer over-etching process to over-etch the upper layer under conditions such that the etching rate for the upper layer is substantially equal to the etching rate for the lower layer after the upper layer main etching step; and performing a lower layer etching process to selectively etch the lower layer after the upper layer over-etching step.

According to this method, the upper layer main etching process is performed under the conditions such that the etching rate for the upper layer is higher than the etching rate for the lower layer in the upper layer main etching step. When the lower layer is exposed by the etching process, the upper layer main etching process is terminated, and the upper layer over-etching process is started. In the upper layer over-etching step, the etching conditions are changed such that the etching rate for the upper layer is substantially equal to the etching rate for the lower layer. Thus, approximately one half of etching species contribute to etching of the upper layer remaining on the lower layer, and the other half of the etching species contribute to etching of the lower layer exposed by removing the upper layer. This suppresses etching of side faces of the resulting upper layer which constitutes a part of the metal interconnection, thereby suppressing an interconnection defect such as variations in resistance which may otherwise occur when an upper layer portion of the metal interconnection is lost.

The metal interconnection may include a first metal interconnection portion having a ring shape, and a second metal interconnection portion provided in a region defined within the first metal interconnection portion.

Particularly, where the metal interconnection has the second metal interconnection portion provided in the region defined within the ring-shaped first metal interconnection portion, the side etching would be more liable to occur on an upper layer portion of the second metal interconnection portion. Therefore, where the present invention is applied to the production method for the semiconductor device having such a construction, the side etching of the upper layer portion of the second metal interconnection portion can be effectively suppressed.

The upper layer may include a titanium nitride sublayer of titanium nitride and a titanium sublayer of titanium provided in stacked relation, and the lower layer may be an aluminum copper layer of an alloy of aluminum and copper.

The foregoing and other objects, features and effects of the present invention will become more apparent from the following description of the preferred embodiment with reference to the attached drawings.

### BRIEF DESCRIPTION OF THE DRAWINGS

FIG. 1 is a plan view of a semiconductor device to be produced by a method according to one embodiment of the present invention.

FIG. 2 is a flow chart showing a process sequence for forming a metal interconnection by patterning.

FIG. 3 are schematic sectional views showing the process sequence for forming the metal interconnection by patterning.

FIG. 4 are schematic sectional views showing a process sequence of a prior art method for forming a metal interconnection by patterning.

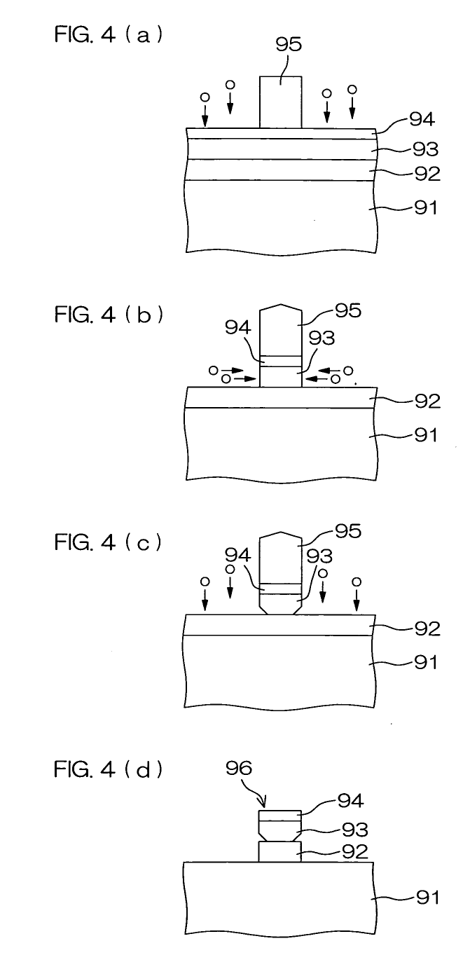

### DESCRIPTION OF REFERENCE CHARACTERS

12: Metal interconnection
13: First metal interconnection portion
14: Second metal interconnection portion
15: AlCu layer
16: Ti/TiN layer

### BEST MODE FOR CARRYING OUT THE INVENTION

An embodiment of the present invention will hereinafter be described in detail with reference to the attached drawings.

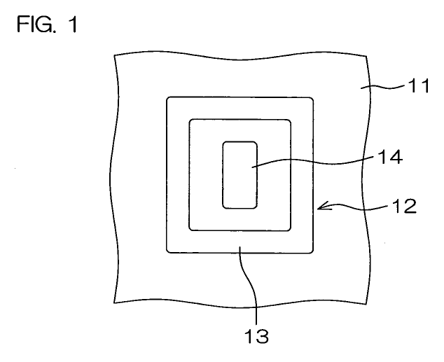

FIG. 1 is a plan view of a semiconductor device to be produced by a method according to one embodiment of the present invention.

The semiconductor device shown in FIG. 1 includes a metal interconnection 12 of a laminate structure formed by patterning on a semiconductor substrate 11 which serves as a base thereof.

The metal interconnection 12 includes, for example, a first metal interconnection portion 13 having a square ring shape, and a second metal interconnection portion 14 provided in a region defined within the first metal interconnection portion 13. The first metal interconnection portion 13 and the second metal interconnection portion 14 are respectively electrically connected to functional devices formed in the semiconductor substrate 11.

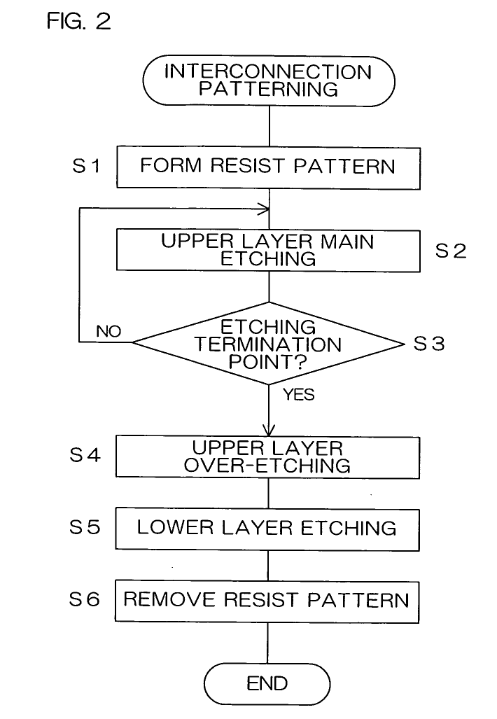

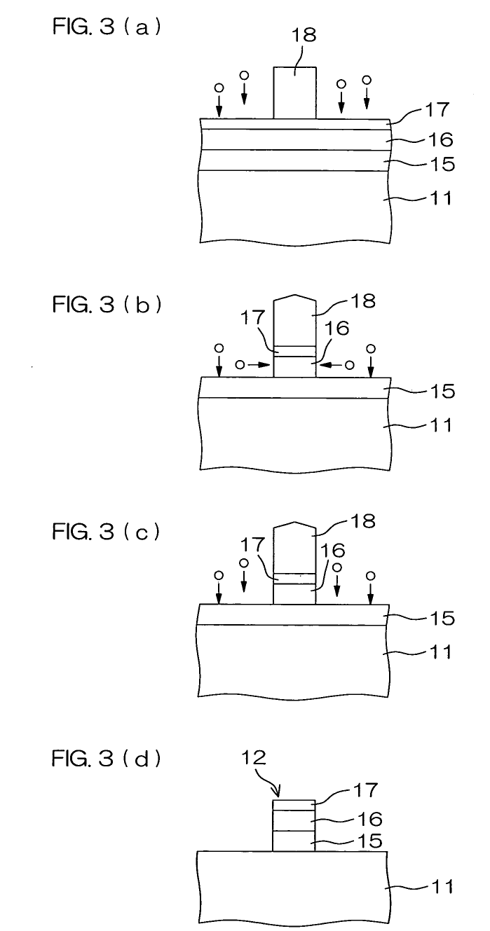

FIG. 2 is a flow chart showing a process sequence for forming the metal interconnection 12 by patterning, and FIG. 3 are schematic sectional views showing the process sequence.

In the process for forming the metal interconnection 12 by patterning, as shown in FIG. 3(a), an AlCu layer 15 of an alloy of Al and Cu, and a Ti/TiN layer 16 of a laminate including a Ti sublayer and a TiN sublayer and a BARC layer 17 are formed in this order in stacked relation on the semiconductor substrate 11. Thereafter, a resist pattern 18 is formed on the BARC layer 17 by a photolithography technique in a metal interconnection formation region in which the metal interconnection 12 (the first metal interconnection portion 13 and the second metal interconnection portion 14) is to be formed (Step S1).

An upper layer etching process is performed to remove unnecessary portions of the Ti/TiN layer 16 and the BARC layer 17 (which are not masked with the resist pattern 18). The upper layer etching process is achieved, for example, by an ICP (Inductively Coupled Plasma) etching apparatus which employs two different radio frequency powers.

With the use of the resist pattern 18 as a mask, the upper layer etching process is performed under conditions such that an etching rate for the Ti/TiN layer 16 and the BARC layer 17 is higher than an etching rate for the AlCu layer 15 (Step S2). More specifically, Cl₂/CHF₃/Ar is employed as an etching gas, and gas flow rates of the respective gases are Cl₂/CHF₃/Ar: 80/10/35 sccm. The internal pressure of a processing chamber (not shown) in which the semiconductor substrate 11 is accommodated is 8 mTorr, and a first radio frequency power RFs and a second radio frequency power RFb are 600 W and 100 W, respectively.

The etching process (upper layer main etching process) performed under the aforesaid conditions is continued until an etching termination point at which the AlCu layer 15 is exposed is detected. When the AlCu layer 15 is exposed with the Ti/TiN layer 16 and the BARC layer 17 removed, the intensity of light emitted due to ions and radicals in a plasma are changed. Therefore, the etching termination point is detected based on a change in the light emission intensity.

When the etching termination point is detected (YES in Step S3), the etching conditions are changed such that the etching rate for the Ti/TiN layer 16 is substantially equal to the etching rate for AlCu layer 15. Under such conditions, an upper layer over-etching process is performed to assuredly remove the unnecessary portion of the Ti/TiN layer 16 from the AlCu layer 15 (Step S4). More specifically, the etching gas is changed to Cl₂/BCl₃/Ar, and the flow rates of the respective gases are changed to Cl₂/BCl₃/Ar: 60/40/40 sccm. The internal pressure of the processing chamber is changed to 10 mTorr, and the first radio frequency power RFs and the second radio frequency power RFb are changed to 350 W and 150 W, respectively.

By thus changing the etching conditions, approximately one half of etching species such as radicals in the plasma contribute to the etching of the unnecessary portion of the Ti/TiN layer 16 remaining on the AlCu layer 15, and the other half of the etching species contribute to the etching of the AlCu layer 15 exposed by removing the Ti/TiN layer 16 and the BARC layer 17 as shown in FIG. 3(b). This suppresses the etching of side faces of the resulting Ti/TiN layer 16 which constitutes a part of the metal interconnection 12 (a portion of the Ti/TiN layer 16 to be left on the AlCu layer 15).

After a lapse of a predetermined period from the start of the upper layer over-etching process, the etching conditions are changed such that the etching rate for the AlCu layer 15 is higher than the etching rate for the Ti/TiN layer 16 and the BARC layer 17. Under such conditions, a lower layer etching process is performed to remove an unnecessary portion of the AlCu layer 15 (which is not masked with the resist pattern 18) as shown in FIG. 3(c) (Step S5). The lower layer etching process is, for example, continued for a lapse of predetermined period after a layer underlying the AlCu layer 15 is exposed by removing the unnecessary portion of the AlCu layer 15.

After termination of the lower layer etching process, the resist pattern 18 on the BARC layer 17 is removed (Step S6). Thus, a pattern of the metal interconnection 12 is provided on the semiconductor substrate 11 as shown in FIG. 3(d).

In the upper layer main etching process for removing the unnecessary portions of the Ti/TiN layer 16 and the BARC layer 17, the etching conditions are such that the etching rate for the Ti/TiN layer 16 and the BARC layer 17 is higher than the etching rate for the AlCu layer 15. When the exposure of the AlCu layer 15 is detected, the upper layer main etching process is terminated, and the upper layer over-etching process is started. For the upper layer over-etching process, the etching conditions are changed such that the etching rate for the Ti/TiN layer 16 is substantially equal to the etching rate for the AlCu layer 15. Thus, approximately one half of the etching species such as radicals in the plasma contribute to the etching of the unnecessary portion of the Ti/TiN layer 16 remaining on the AlCu layer 15, and the other half of the etching species contribute to the etching of the AlCu layer 15 exposed by removing the Ti/TiN layer 16 and the BARC layer 17. This suppresses the etching of the side faces of the resulting Ti/TiN layer 16 which constitutes a part of the metal interconnection 12, thereby suppressing an interconnection defect such as variations in resistance which may otherwise occur when a portion of the metal interconnection 12 formed from the Ti/TiN layer 16 and the BARC layer 17 is lost.

While the present invention has been described in detail by way of the embodiment thereof, it should be understood that the embodiment is merely illustrative of the technical principles of the present invention but not limitative of the invention. The spirit and scope of the present invention are to be limited only by the appended claims.

For example, another Ti/TiN layer of a laminate including a Ti sublayer and a TiN sublayer may be provided immediately below the AlCu layer 15. In this case, another etching process for removing an unnecessary portion of the Ti/TiN layer (exposed by the removal of the AlCu layer 15) is performed after the termination of the lower layer etching process for the removal of the unnecessary portion of the AlCu layer 15.

Although the numerical values are specified by way of example for the etching conditions for the upper layer main etching process and the upper layer over-etching process in the embodiment described above, some of the etching conditions may be changed, as required, according to the other etching conditions such as the first radio frequency power RFs and the second radio frequency power RFb.

This application corresponds to Japanese Patent Application No. 2005-327696 filed in the Japanese Patent Office on Nov. 11, 2005, the disclosure of which is incorporated herein by reference.

What is claimed is:

1. A semiconductor device production method for producing a semiconductor device having a metal interconnection by etching a metal film including a lower layer of a first metal material and an upper layer of a second metal material different from the first metal material, the method comprising the steps of:
performing an upper layer main etching process to selectively etch the upper layer under conditions such that an etching rate for the upper layer is higher than an etching rate for the lower layer, the upper layer main etching process being terminated when the lower layer is exposed by the etching process;
performing an upper layer over-etching process to over-etch the upper layer under conditions such that the etching rate for the upper layer is substantially equal to the etching rate for the lower layer after the upper layer main etching step; and
performing a lower layer etching process to selectively etch the lower layer after the upper layer over-etching step.

2. A semiconductor device production method as set forth in claim 1, wherein the metal interconnection includes a first metal interconnection portion having a ring shape, and a second metal interconnection portion provided in a region defined within the first metal interconnection portion.

3. A semiconductor device production method as set forth in claim 1, wherein
the upper layer includes a titanium nitride sublayer of titanium nitride and a titanium sublayer of titanium provided in stacked relation, and
the lower layer is an aluminum copper layer of an alloy of aluminum and copper.
